(19) United States
(12) Patent Application Publication
(10) Pub. No.: US 2023/0273123 A1
(43) Pub. Date: Aug. 31, 2023

(54) Structure of thermal stress release of photo-excited thermal infrared emitter

(71) Applicant: Godsmith Microelectronics Inc., Hsinchu (TW)

(72) Inventor: Jin-Shown SHIE, Hsinchu (TW)

(21) Appl. No.: 17/682,014

(22) Filed: Feb. 28, 2022

(51) Int. Cl. G01N 21/3563

(52) U.S. Cl. CPC G01N 21/3563; G01N 2201/0612; G01N 2021/3568

(57) ABSTRACT

A structure of thermal stress release of photo-excited thermal infrared emitter includes a substrate, a VCSEL unit, a frame, and a layered structure. The VCSEL unit has a small emission angle disposed on a portion of the substrate. The frame is disposed on the substrate, and has an interior side wall inclinedly extended upwardly to form a cavity in which the portion of the substrate is to be exposed. The layered structure is above the VCSEL unit and includes a first light-transparent passivation layer, a light absorbing and thermal infrared emitting layer, and a second light-transparent passivation layer formed in sequence for chemical protection. The light absorbing and thermal infrared emitting absorbs light emitted from the VCSEL unit to generate infrared radiation, and has a layout geometry of reticulated mosaic size such that thermal expansion mismatch and induced stress are minimized without accumulation due to small reticulated mosaic size.

### TECHNICAL FIELD

The present disclosure relates to thermal infrared emitter, and more particularly, to photo-excited thermal infrared emitter with thermal-stress reduced structure on the heat absorption membrane layers of the emitter.

### BACKGROUND

Light-emission and Light-detection based gas sensors such as the non-dispersive infrared (NDIR) gas sensors have been widely used for gas measurement. NDIR gas sensors possess many advantages over other types of gas sensors. Comparing to the traditional gas sensors, NDIR gas detections have the optical advantage of non-direct contact measurement between the active sensing film and the sensed substance; thus is highly reliable and excellent longevity. The optical detection also provides fast response and high sensitivity.

All NDIR gas detector units include, essentially, the following three elements: an infrared emission source, an infrared sensor element and a gas chamber to confine the gas and measure its concentration.

In the U.S. Pat. No. 11,004,997 B2 disclosed by Jin-Shown Shie and et al. describes a unique MEMS-type infrared thermal emitter, entitled as photo-excited thermal infrared emitter. Unlike most of the present MEMS-type emitters (for example, electro-thermal chip-type infrared emitting device), it doesn't contain resistive heating element deposited directly on the IR emitting membrane; instead, the IR emitting membrane contains a light absorbing layer of semiconductor material that absorbs the external light source in proximity then converting into heat due to non-radiative recombination, and heating up the membrane up to elevate temperature while simultaneously emits thermal infrared radiation as an incandescent lamp. As shown in FIG. 1A and FIG. 1B, said photo-excited thermal infrared emitter includes a substrate 900, a light-emitting unit 901, a thermal-infrared-emitting membrane unit 902 and a frame 903. The light-emitting unit 901, mostly probably a low-cost visible to near infrared LED, is disposed on said substrate 900 in a laminating direction L and has a light-exiting surface away from said substrate. The thermal-infrared-emitting membrane unit 902 includes a light-absorbing-infrared-emitting conversion unit (abb. as IR emitter unit) 902a that is disposed on said substrate 900 in the laminating direction L to cover said light-emitting unit 901 without physical contact. Said IR thermal-infrared-emitting membrane unit 902 is composed of a layered structure of semiconductor material to absorb the light from said light-emitting unit 901 in proximity. The IR emitter unit 902a is sandwiched by passivation layers 902b and 902c on both sides to protect the IR emitter unit 902a being chemically attacked during the formation of thermally isolated floating emitter membrane. The semiconductor membrane, such as polycrystalline silicon, absorbs external light and generates electron-hole pairs, non-radiative recombination of electron and hole quickly occurs and turns the released energy into heat in the membrane because of lacking external current loop for charge flow. And also because of excellent thermal isolation of said membrane, the side heat rises up quickly as the membrane is heated to elevated temperature to emit blackbody-like continuous spectra as that of an incandescent lamp, including the infrared useful for NDIR applications.

The photo-excited thermal IR emitter has following advantages in comparison with conventional electro-thermal chip-type infrared-emitting device: 1) due to the absence of metallic element on the membrane as the electrical heating element, severe thermal stress generated between the metal heater and its passivation layer is eliminated which is caused by large thermal expansion difference and harmful to the membrane when it is operated in severe conditions of large temperature span and cycling as that required by an IR emitter; 2) these metallic heater materials, such as Platinum, which has been used in the current commercial products are non-standard IC materials and is difficult to be processed in IC foundry for cost reason and compatibility; 3) for electro-thermal chip-type infrared emitting device, due to low electrical resistivity of metal conductor as Joule heating material, it is hard to design and fabricate the resistive heater with proper value on the tiny MEMS membrane area to provide suitable amount of heating power with a general operation voltage of few volts, in most of cases too large amount of induced current will overpower the device. On the other hand, lowering the applied voltage to fractional volt to solve the aforementioned problem would waste power to external circuit and lead to less heating efficiency and not practical.

The harmful conditions of the electro-thermal chip-type infrared-emitting device are solvable if the heating source is not in contact with the membrane but presented externally, such as that disclosed in the U.S. Pat. No. 11,004,997 B2 described in above.

In despite of said photo-excited IR emitter has grater thermal advantage; however, for larger area of emission membrane (IR emitter unit 902a) and more severe optional condition, further reduction of the thermal stress still has to be considered. A further improvement of reducing the thermal stress is needed.

### BRIEF SUMMARY

The present disclosure relates to a structure of thermal stress release of photo-excited thermal infrared emitter. The structure comprises a substrate, a vertical cavity surface emitting laser (VCSEL) unit, a frame and a layered structure. The VCSEL unit has a small emission angle disposed on a portion of a main surface of the substrate, wherein an emission wavelength of the VCSEL unit is below 950 nm. The frame is disposed on the substrate, the frame defines a cavity in which the portion of the main surface of the substrate is to be exposed, wherein the frame has an interior side wall inclinedly extended upwardly to form the cavity as an upward convex structure. The layered structure disposed in proximity above the VCSEL unit, the layered structure includes a first light-transparent passivation layer, a second light-transparent passivation layer and a light absorbing and thermal infrared emitting layer. The light absorbing and thermal infrared emitting is configured to align with the VCSEL unit and is heated up after absorbing light emitted from the VCSEL unit to generate infrared radiation, and the light absorbing and thermal infrared emitting layer is sandwiched between the first light-transparent passivation layer and the second light-transparent passivation layer for chemical protection during formation. The light absorbing and thermal infrared emitting layer has a layout geometry of reticulated mosaic size such that thermal expansion mismatch and induced stress in between the light absorbing and thermal infrared emitting layer. The first light-transparent passivation layer and the second light-transparent passivation layer are minimized without accumulation due to small reticulated mosaic size.

Further embodiments are defined in the dependent claims. Those skilled in the art will recognize additional features and advantages upon reading the following detailed description and on viewing the accompanying drawings.

### BRIEF DESCRIPTION OF THE SEVERAL VIEWS OF THE DRAWINGS

In the drawings, identical reference numbers identify similar elements or acts unless the context indicates otherwise. The sizes and relative portions of the elements in the drawings are not necessarily drawn to scale.

FIGS. 1A to 1B show a schematic perspective view of a thermal infrared emitter in accordance with prior art.

FIGS. 2A to 2B show a schematic perspective view of a thermal infrared emitter in accordance with the disclosure.

### DETAILED DESCRIPTION

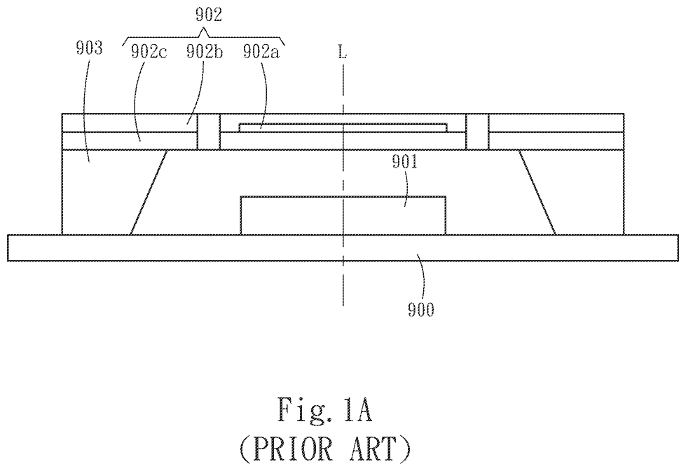

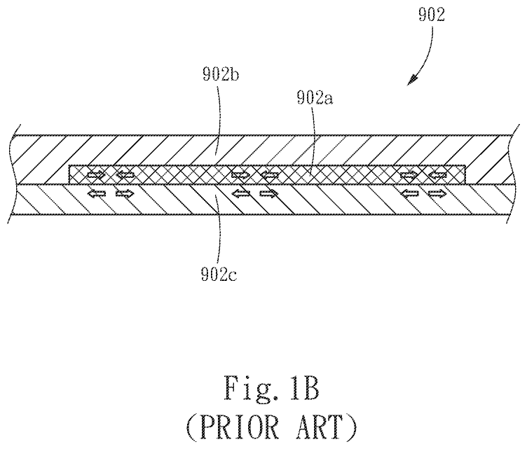

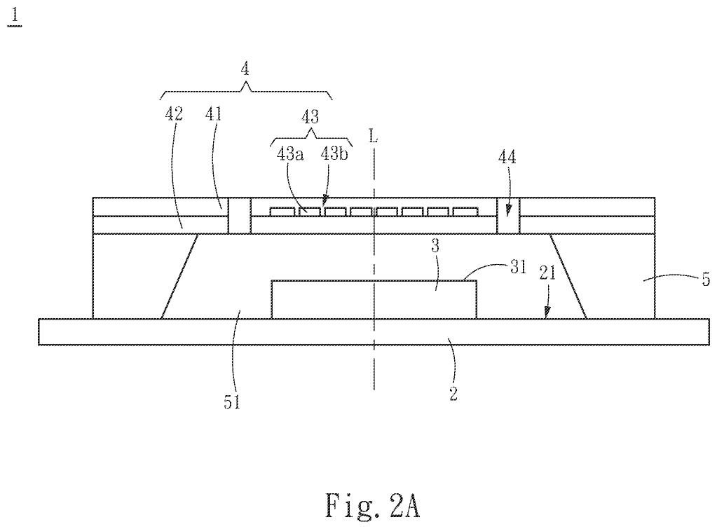

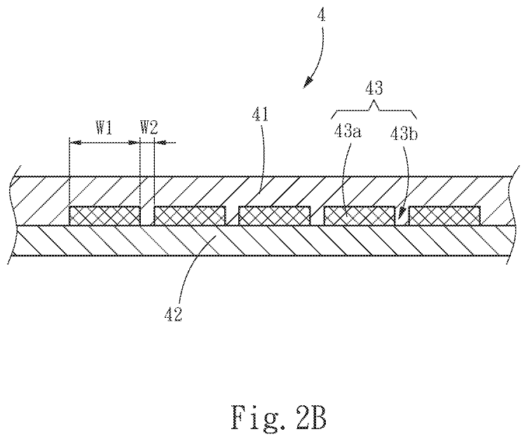

The large membrane as disclosed in FIGS. 1A and 1B causes accumulation of the thermal stress due to the thermal expansion mismatch. Further reduction of the thermal stress due to mismatch of the light absorbing layer and the passivation layers is achieved by forming the absorbing layer into a reticulate structure as shown in FIGS. 2A and 2B.

In the following detailed description, reference is made to the accompanying drawings, which form a part hereof and in which are shown byway of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

Unless the context requires otherwise, throughout the specification and claims that follow, the word “comprise” and variations thereof, such as “comprises” and “comprising,” are to be construed in an open, inclusive sense, that is, as “including, but not limited to.” The articles “a”, “an” and “the” are intended to include the plural as well as the singular, unless the context clearly indicates otherwise.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Referring to FIGS. 2A and 2B, an embodiment of a structure 1 of thermal stress release of photo-excited thermal infrared emitter of this disclosure includes a substrate 2, a light-emitting unit 3, a layered structure 4 and a frame 5.

The light-emitting unit 3 and the layered structure 4 are disposed on the substrate 2. Example of the substrate 2 may include a circuit board such as a ceramic circuit board or a printed circuit board (PCB). The substrate 2 may be used as an intermediate for electrically connecting the light-emitting unit 3 to an external control device or other device (not shown).

The light-emitting unit 3 is disposed on the substrate 2 in a laminating direction (L), and has a light-exiting surface 31 opposite to the substrate 2. In certain embodiments, the light-emitting unit 3 is a vertical cavity surface emitting laser (VCSEL) unit having a small emission angle and is disposed on a portion of a main surface 21 of the substrate 2. The VCSEL unit's emission wavelength is below 950 nm.

The frame 5 is disposed on the substrate 2, surrounds the light-emitting unit 3, and has a cavity 51 in which the light-emitting unit 3 is centrally disposed. The frame 5 protects the light-emitting unit 3 and provides support to the layered structure 4 such that the layered structure 4 is disposed above and spaced apart from the light-exiting surface 31 of the light-emitting unit 3. An example of the frame 5 may include, but is not limited to, a silicon wafer having a thickness of 300 μm. In an exemplary embodiment, a surface of the silicon wafer that is to be connected to the substrate 2 may be subjected to anisotropic wet etching so as to form the cavity 51 having an inclined inner wall that is tapered upwardly. The use of anisotropic wet etching on the silicon wafer to form the cavity 51 has several advantages, including a short time period, inexpensive, and is compatible with existing semiconductor process technologies. In certain embodiments, the frame 5 may be subjected to dry etching so as to form the cavity 51 having a vertically straight inner wall according to actual requirements, and is not limited to using the silicon wafer, and thus formation thereof is not limited to the aforesaid.

The layered structure 4 is connected to the frame 5 so as to cover the cavity 51 and the light-emitting unit 3. The layered structure 4 includes a first layer 41, a second layer 42 and a light absorbing and thermal infrared emitting layer 43. The first layer 41 and the second layer 42 is a light-transparent passivation layer, respectively, which is transparent to an excitation light emitted from the light-emitting unit 3. The light absorbing and thermal infrared emitting layer 43 is sandwiched between the first layer 41 and the second layer 42, and is disposed on the substrate 2 in the laminating direction (L) to cover the light-emitting unit 3. The first and second layers 41, 42 could be treated as an upper passivation layer and a lower passivation layer for the purpose of protecting said light absorbing and thermal infrared emitting layer 43 from chemical attack during its forming process. The first and second layers 41, 42 stacked on each other and disposed on the frame 5 may be used as etch stop layers when the frame 5 is etched, and for protecting the light absorbing and thermal infrared emitting layer 43. Examples of a material suitable for making each of the first layer 41 and the second layer 42 include, but are not limited to, silicon nitride, silicon carbide, gallium nitride, zirconium oxide, magnesium oxide, and combinations thereof. The light absorbing and thermal infrared emitting layer 43 is sandwiched between the first and second layers 41, 42 and is disposed immediately adjacent to the light-exiting surface 31 of the light-emitting unit 3, such that the light absorbing and thermal infrared emitting layer 43 is aligned with the light-emitting unit 3 in the laminating direction (L) for absorbing light emitted from the light-exiting surface 31 of the light-emitting unit 3 so as to be heated up and to generate infrared radiation. In certain embodiments, the thus generated infrared radiation has a wavelength ranging from 3 to 25 μm. For example, the thus generated infrared radiation may be thermal infrared radiation that includes mid-wavelength infrared radiation and long-wavelength infrared radiation.

In this embodiment, the light absorbing and thermal infrared emitting layer 43 has a bottom surface with a dimension which is substantially equals to that of the light-exiting surface 31 of the light-emitting unit 3. Examples of a material suitable for making the light absorbing and thermal infrared emitting layer 43 include, but are not limited to, polycrystalline silicon, silicon carbide, germanium, and gallium nitride. The light absorbing and thermal infrared emitting layer 423 may be made of any material whichever suitable for high absorption efficiency of the excitation light.

In certain embodiments, the layered structure 4 further has at least one through hole 44 that penetrates the first and second layers 41, 42 and that is spaced apart from the light absorbing and thermal infrared emitting layer 43 for reducing heat transfer from the light absorbing and thermal infrared emitting layer 43. In this embodiment, the layered structure 4 has a plurality of the through holes 44 that penetrate the first and second layers 41, 42 and that surround the light absorbing and thermal infrared emitting layer 43. A portion of the first and second layers 41, 42 located among the through holes 44 forms a plurality of linkers such that the light absorbing and thermal infrared emitting layer 43 and another portion of the first and second layers 41, 42 covering the light absorbing and thermal infrared emitting layer 43 are suspended above the light-emitting unit 3.

In an exemplary embodiment, the first and second layers 41, 42 and the light absorbing and thermal infrared emitting layer 43 are deposited by low-pressure chemical vapor deposition (LPCVD), in which each of the first and second layers 41, 42 having a thickness of 0.16 μm is made from silicon nitride, and the light absorbing and thermal infrared emitting layer 43 is made from polycrystalline silicon. In another exemplary embodiment, the light absorbing and thermal infrared emitting unit 4 has a thickness of not less than 0.7 μm, which allows the light absorbing and thermal infrared emitting layer 43 to absorb the light emitted from the light-emitting unit 3 to the utmost extent, but is not limited thereto.

Although thermal expansion coefficients of polycrystalline silicon and silicon nitride are closed to each other, a slight difference in the thermal expansion coefficients between the first and second layers 41, 42 and the light absorbing and thermal infrared emitting layer 43 still leads to excessive thermal stress during operation under a high temperature.

To overcome the aforesaid problem, the light absorbing and thermal infrared emitting layer 43 is formed in a reticulate pattern and comprises a plurality of light-absorbing mosaic blocks 43a. The light-absorbing mosaic blocks 43a are laterally spaced apart from one another so as to form a plurality of gaps 43b between the adjacent light-absorbing mosaic blocks 43a. Each of the light-absorbing mosaic blocks 43a may have a same or different shape. For example, the light-absorbing mosaic blocks 43a are shaped as a regular shape or an irregular shape, which has a shape of a circle, an ellipse, an oval, a polygon, a triangle, a quadrilateral, a square, a rectangle, a trapezoid, a parallelogram, a pentagon, a hexagon, a heptagon, an octagon or any other shapes as long as the overall geometry construction can be compact and expandable. The reticulate pattern of the light absorbing and thermal infrared emitting layer 43 is configurated in such a manner that a width of the gap 43b between the adjacent light-absorbing mosaic blocks 43a is sufficient to tolerate a thermal expansion of the light-absorbing mosaic blocks 43a by heating. In an exemplary embodiment, a ratio of a width (W1) of the light-absorbing mosaic block 43a and a width (W2) of the gap 43b is between 50 and 150. In an example, the ratio is around 100.

The light absorbing and thermal infrared emitting layer 43 is divided into the plurality of light-absorbing mosaic blocks 43a. The plurality of light-absorbing mosaic blocks 43a are substantially aligned horizontally to form a two dimensional array when seen from a top-view and each of the light-absorbing mosaic blocks 43a is spaced from the adjacent light-absorbing mosaic blocks 43a to leave the plurality of gaps 43b between adjacent rows or columns. By dividing the light absorbing and thermal infrared emitting layer 43 into the plurality of light-absorbing mosaic blocks 43a, thermal expansion mismatch and induced stress in between the light absorbing and thermal infrared emitting layer 43, the first layer 41 and the second layer 42 are minimized without accumulation due to small mosaic size of the light-absorbing mosaic blocks 43a. As such, the micro crack in the light absorbing and thermal infrared emitting layer 43 or at the interface caused by the thermal expansion mismatch could be alleviated. Thermal crack and thermal stress concentration during heating is minimized or even avoided.

In summary, the infrared-radiation device 1 of the present disclosure, by virtue of the light absorbing and thermal infrared emitting layer 43 being disposed immediately adjacent to the light-exiting portion 31 of the light-emitting unit 3 through alignment in the laminating direction (L), the light absorbing and thermal infrared emitting layer 43 can absorb most of the light emitted by the light-emitting unit 3 so as to be heated up and to generate infrared radiation effectively. In addition, the aforesaid material and thickness of the layered structure 4 allows the light absorbing and thermal infrared emitting layer 43 to be operated at a high temperature so that the energy conversion efficiency can be improved.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A structure of thermal stress release of photo-excited thermal infrared emitter, comprising:
a substrate:
a vertical cavity surface emitting laser (VCSEL) unit having a small emission angle disposed on a portion of a main surface of the substrate, wherein an emission wavelength of the VCSEL unit is below 950 nm;
a frame disposed on the substrate, the frame defines a cavity in which the portion of the main surface of the substrate is to be exposed, wherein the frame has an interior side wall inclinedly extended upwardly to form the cavity as an upward convex structure; and
a layered structure disposed in proximity above the VCSEL unit, the layered structure includes a first light-transparent passivation layer, a second light-transparent passivation layer and a light absorbing and thermal infrared emitting layer, wherein the light absorbing and thermal infrared emitting that is configured to align with the VCSEL unit and is heated up after absorbing light emitted from the VCSEL unit to generate infrared radiation, and the light absorbing and thermal infrared emitting layer is sandwiched between the first light-transparent passivation layer and the second light-transparent passivation layer for chemical protection during formation;
wherein the light absorbing and thermal infrared emitting layer has a layout geometry of reticulated mosaic size such that thermal expansion mismatch and induced stress in between the light absorbing and thermal infrared emitting layer, the first light-transparent passivation layer and the second light-transparent passivation layer are minimized without accumulation due to small reticulated mosaic size.

2. The structure of claim 1, wherein the frame is formed by a front side bulk micromachining of anisotropic etching on a silicon wafer.
